(19) United States
(12) Patent Application Publication
(10) Pub. No.: US 2010/0032232 A1
(43) Pub. Date: Feb. 11, 2010

(54) SPEAKER DEVICE AND DISPLAY APPARATUS HAVING THE SAME

(75) Inventor: Soo-chan LIM, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/504,943

(22) Filed: Jul. 17, 2009

(30) Foreign Application Priority Data
Aug. 11, 2008 (KR) 10-2008-0078320

(51) Int. Cl. H04R 1/02; H05K 5/00

(52) U.S. Cl. 181/141; 181/148

(57) ABSTRACT

A speaker device of a video display apparatus which realizes a high quality sound by improving a bass property even in the case that an enclosure unit has a smaller internal volume than that a speaker unit should basically have is provided. The speaker device includes at least one speaker unit, an enclosure unit which contains and supports the speaker unit and has an opening formed on a side surface thereof, and a cover which closes and seals the opening of the enclosure unit and is movable by an air movement inside the enclosure unit. The cover is formed of a material which is not permeable to air, and this material may be at least one of resin, textile, vinyl and paper. The cover may be formed of a foam rubber of an elastomeric system.

### CROSS-REFERENCE TO RELATED APPLICATIONS

This application claims priority from Korean Patent Application No. 10-2008-78320, filed Aug. 11, 2008, in the Korean Intellectual Property Office, the entire disclosure of which is hereby incorporated by reference.

### BACKGROUND OF THE INVENTION

1. Field of the Invention

Methods and apparatuses consistent with the present invention relate to an improved speaker device embedded in a display apparatus such as a Liquid Crystal Display (LCD) or Plasma Display Panel (PDP) TV and a display apparatus having the same.

2. Description of the Related Art

A speaker device is of importance in the video display apparatus field for high quality sound that accompanies the watching of a Pulse-Code Modulation (PCM) broadcast through a sound multiplex television broadcast or a satellite broadcast and a video program of a video disk or a video tape.

The speaker device used in the video display apparatus includes a speaker unit and an enclosure unit which contains and supports the speaker unit to form a resonant space.

In order for the speaker device to realize highest sound pressure and bass performance, the resonant space formed by the enclosure unit should have a sufficient internal volume. That is, the internal volume of the resonant space should be larger than the internal volume which the speaker unit occupies in the enclosure unit.

However, as there is a growing trend toward slimness in size of the video display apparatus such as an LCD or PDV TV, an installation space for the speaker device in the video display apparatus is reduced and thus sizes of both of the speaker unit and the enclosure unit are reduced.

If the resonant space formed by the enclosure unit has a smaller internal volume than the desirable internal volume for the speaker unit in the related art because of the slimness of the speaker device, sound quality deteriorates and in particular bass property significantly deteriorates such that an unstable and unnatural sound is output.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides a speaker device which realizes a high quality sound by improving a bass property even in the case that an enclosure unit has a smaller internal volume than the desirable internal volume for a speaker unit in the related art, and a video display apparatus having the same.

According to an aspect of the present invention, there is provided a speaker device, including at least one speaker unit, an enclosure unit which contains and supports the speaker unit and has an opening formed on a side surface thereof, and a cover which closes and seals the opening of the enclosure unit and is movable by an air movement inside the enclosure unit.

The cover may be formed of a material which is not permeable to air, and this material may be at least one of resin, textile, vinyl and paper. The cover may be formed of a foam rubber of an elastomeric system.

The cover may be attached by an adhesive or a double side tape.

The cover may have a thickness of 1˜3 mm.

The opening may be formed on a bottom surface of the enclosure unit.

According to another aspect of the present invention, there is provided a speaker device for a video display apparatus, including at least one speaker unit, and an enclosure unit which encloses the speaker unit to form a resonant space with respect to the speaker unit, and the resonant space has an internal volume which is smaller than the desirable internal volume for the speaker unit in the related art, and an opening is formed on a bottom surface of the enclosure unit and a cover is disposed on the opening for closing and sealing the opening and the cover is formed of a material which is not permeable to air and is movable by air movement in the resonant space.

According to still another aspect of the present invention, there is a provided a display apparatus which has a speaker device described above, which is located to the right and left of a display unit.

The speaker device may be embedded in a lower portion of the display unit in a symmetrical pattern, and the speaker device may have a speaker unit located to as to face downward.

### BRIEF DESCRIPTION OF THE DRAWINGS

The above and other aspects of the present invention will become apparent and more readily appreciated from the following description of the exemplary embodiments, taken in conjunction with the accompany drawings of which:

FIG. 1 is a front perspective view illustrating a speaker device according to an exemplary embodiment of the present invention;

FIG. 2 is an exploded perspective view illustrating the speaker device according to an exemplary embodiment of the present invention;

FIG. 3 is a perspective view illustrating a cover according to an exemplary embodiment of the present invention;

FIG. 4 is a rear perspective view illustrating the speaker device according to an exemplary embodiment ofthe present invention;

FIG. 5 is a graph for showing an improvement in a bass property achieved by the speaker device according to an exemplary embodiment of the present invention; and

FIG. 6 is a front view illustrating a video display apparatus having the speaker device according to an exemplary embodiment of the present invention.

### DETAILED DESCRIPTION OF EXEMPLARY EMBODIMENTS

Certain exemplary embodiments of the present invention will be described in greater detail with reference to the accompanying drawings.

In the following description, the same drawing reference numerals are used for the same elements even in different drawings. The matters defined in the description such as the detailed construction and elements are provided to assist in a comprehensive understanding of the invention. Thus, it is apparent that the exemplary embodiments of the present invention can be carried out without those specifically defined matters. Also, well-known functions or constructions are not described in detail since they would obscure the invention with unnecessary detail.

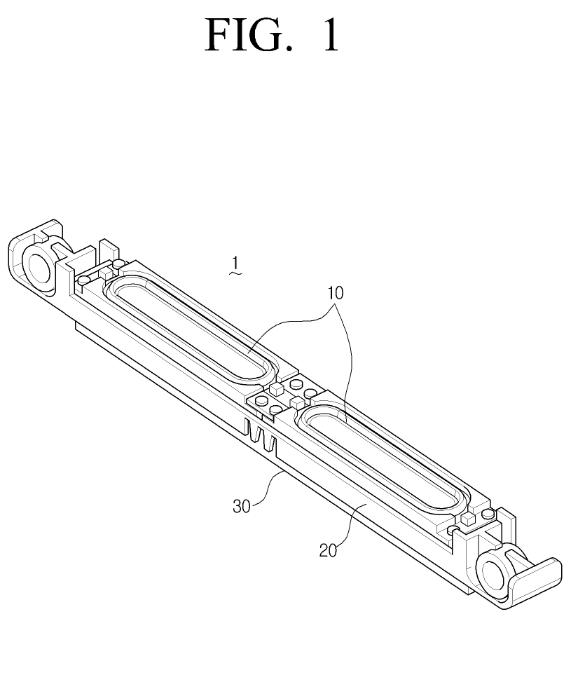

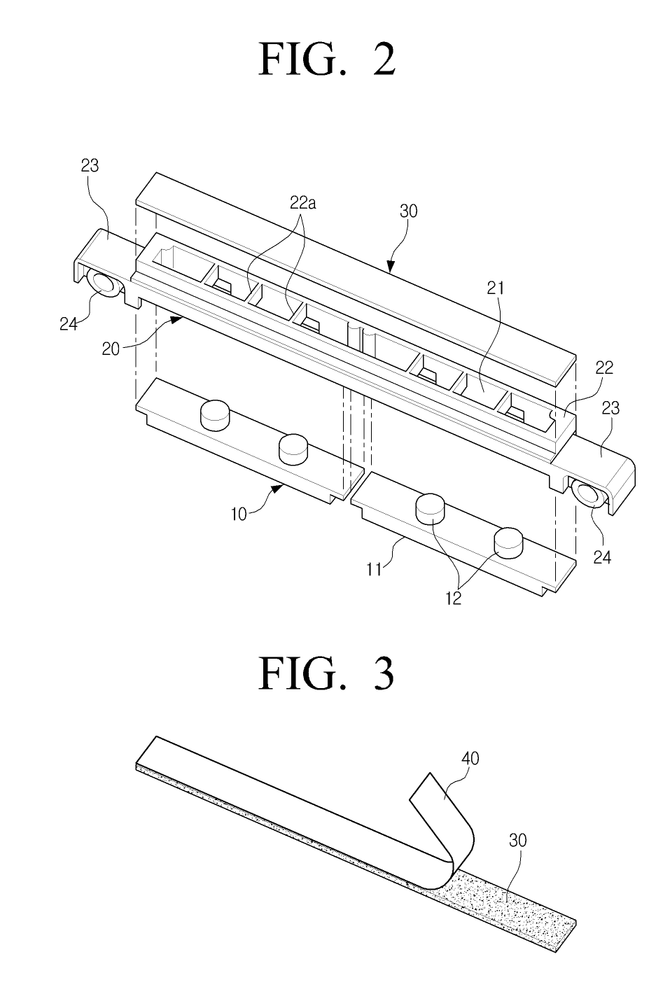

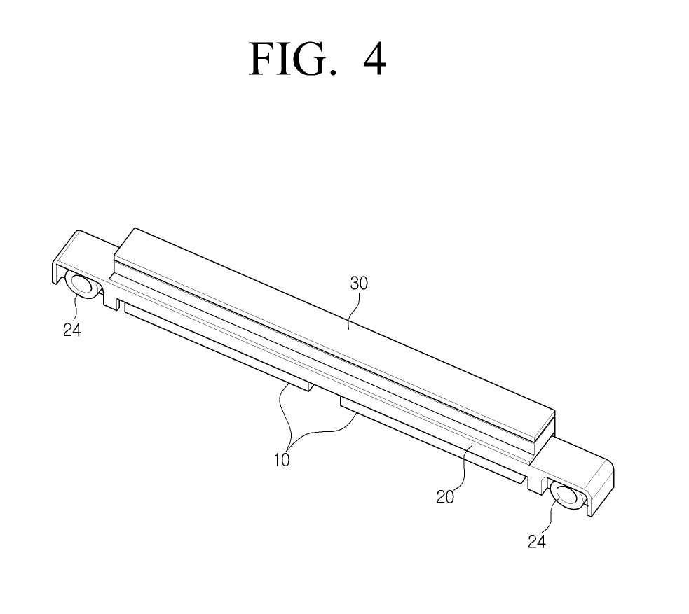

As shown in FIGS. 1 to 4, a speaker device 1 according to an exemplary embodiment of the present invention includes a speaker unit 10, an enclosure unit 20, and a cover 30.

The speaker unit 10 includes an oscillating plate 11 and a ferrite magnet 12. One or more speaker units 10 may be employed, and in this exemplary embodiment, two speaker units 10 are employed. Also, the speaker unit 10 may have, but is not limited to, a conical oscillating plate or a rectangular oscillating plate 11 as shown in the drawings. Two ferrite magnets 12 are provided on a rear surface of each oscillating plate 11. A plurality of magnets 12 may be provided. In an exemplary embodiment, one to four ferrite magnets may be provided.

The enclosure unit 20 contains and supports the speaker unit 10 and has an internal volume. The internal volume of the enclosure unit 20 should be equal to or greater than the volume of speaker unit 10 employed therein. However, as a video display apparatus using the speaker device becomes slimmer, a space occupied by the speaker device in a video display apparatus is reduced and accordingly the speaker device becomes smaller which in turn causes the internal volume of the enclosure unit 20 to be designed smaller than what would be desirable for speaker units in the related art. Therefore, there have been problems of deteriorations in sound quality and bass property.

In order to solve these problems, the enclosure unit 20 has an opening 21 formed on a surface thereof and the cover 30 is provided so as to prevent air from passing through the opening 21 but is movable by air movement inside the enclosure unit 20. Therefore, as the speaker unit 10 oscillates, the cover 30 is moved by a minute width, thus improving the bass property. That is, even if the internal volume of the enclosure unit 20 is smaller than the desirable internal volume for speaker unit in the related art, the present invention exhibits improvement in bass property similar to that which can be achieved by the enclosure unit 20 having a sufficiently large internal volume.

The opening 21 of the enclosure unit 20 is formed on a bottom surface of a body 22 of the enclosure unit 20 which is injection-molded with a comparatively hard plastic material, i.e., on an opposite surface to a surface where the speaker unit 10 is contained, and fixing parts 23 are formed at opposite sides of the body 22. A plurality of ribs 22a are formed in the body 22 and a dustproof rubber 24 is disposed at each of the fixing parts 23. The enclosure unit 20 described above contains and supports the speaker unit 10 such that a resonant space is formed inside the enclosure unit 20. For the reason described above, the resonant space has a smaller internal volume, which deteriorates sound quality. The present invention addresses this sound quality deterioration problem, which is caused by a small resonant space, by attaching the movable cover 30 to the opening 21 of the enclosure unit 20.

The cover 30 is attached to the bottom surface of the body 22 of the enclosure unit 20 by an adhesive or a double side tape 40 (see FIG. 3) to close and seal the opening 21 of the enclosure unit 20. Although the thickness of the cover 30 is not limited, a very thick cover 30 is not recommended in consideration of the trend toward sliminess. In an exemplary embodiment, a cover has a thickness of about 1-3 mm. Also, a material for the cover 30 is not limited. In an exemplary embodiment, a material for the cover is movable by air movement inside the enclosure unit 20 but the material for the cover is not permeable to the air. In an exemplary embodiment, a foam rubber of an elastomeric system may be used as shown in FIG. 3. However, if the cover material is not permeable to the air and is movable by air movement, material such as, but not limited to, resin, textile, vinyl and paper may be used.

In the speaker device configured above according to an exemplary embodiment of the present invention, a sound is replayed as a current is applied due to an electric conversion from an audio signal and thus the speaker unit 10 oscillates, which moves the cover 30 provided on the opening 21 ofthe enclosure unit 20, by a small width, thereby replaying a bass sound and outputting a stable and natural sound.

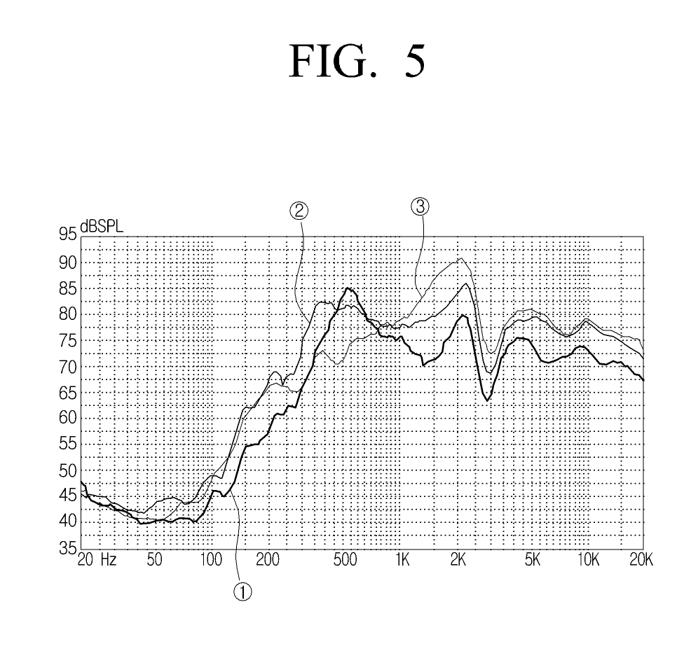

That is, if a sealed and closed enclosure unit made of a comparatively hard plastic material has an internal volume smaller than that which is typically desired of a speaker unit in the related art, a base of about 65 dB is generated at a frequency of 300 Hz as depicted by curve \textcircled{1} of the graph of FIG. 5. However, an exemplary embodiment of the present invention shows a bass of about 75 dB at a frequency of 300 Hz as depicted by curve \textcircled{2}.

FIG. 5 shows results of reproducing a bass in an experiment of an exemplary embodiment using a speaker device employing a closed type enclosure unit, a speaker device of the present invention and a speaker device employing an open type enclosure unit, and curve \textcircled{3} shows a result of the open type enclosure unit. As shown in the graph, the open type enclosure unit replays a bass of about 65 dB at a frequency of 300 Hz.

Also, as can be seen from the graph, for the closed type, a sound abruptly peaks at 500 Hz because of a smaller internal volume of the enclosure unit. However, for an exemplary embodiment of the present invention, sound does not peak at 500 Hz. On the other hand, for the open type, a replay sound is low at 500 Hz and sound abruptly peaks at 2 KHz.

In conclusion, the speaker device according to the exemplary embodiment of the present invention obtains a comparatively stable replay sound in the frequency range of 300 Hz to 2 KHz, whereas the closed type or open type show an unstable fluctuation in the sound.

The speaker device according to an exemplary embodiment includes the enclosure unit 20 having a surface opened and the cover 30 made of a material having a mobility to cover the opening, so that a part of a sound wave generated in the enclosure unit 20 is damped by the cover 30. Accordingly, an abnormal noise caused by a sound wave colliding with a hard wall of the closed type enclosure unit can be reduced.

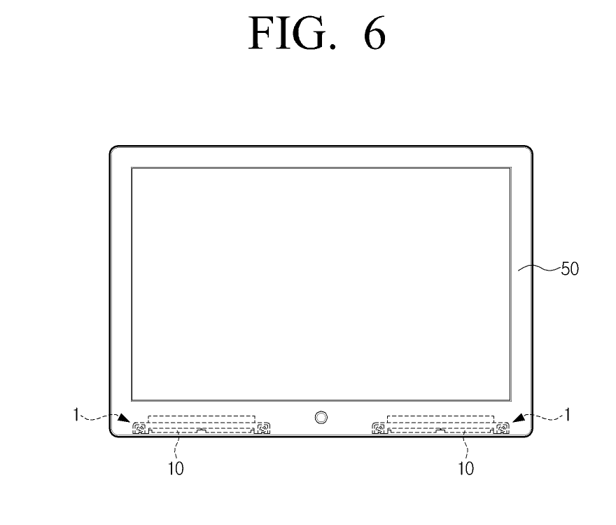

FIG. 6 illustrates an LCD TV, which is an example of a video display device to which the speaker device 1 according to the exemplary embodiment of the present invention is applied. As shown in FIG. 6, the speaker devices 1 are located at opposite sides of a display 50 of the video display apparatus. The speaker devices 1 are embedded in the video display apparatus at lower sides of the display 50 in a symmetrical pattern with the speaker unit 10 being disposed so as to face downward.

In the speaker device 1 according to the exemplary embodiment of the present invention, when the speaker unit 10 oscillates as a current is applied by an electric conversion from an audio signal, the cover 30 disposed on the enclosure unit 20 is moved by a small width, thereby providing a best sound property despite the small internal volume of the enclosure unit 20.

That is, the present invention exhibits the same effect in a frequency property as the case in which the enclosure unit has a large internal volume, despite of the small internal volume of the enclosure unit 20 because the cover 30 has mobility.

Accordingly, a sound replay of a high frequency is improved, a low sound pressure is improved by a strong damping action with a small amount of air, and in particular, bass property is improved, so that a high quality sound can be realized.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A speaker device, comprising:
an enclosure which contains a speaker, the enclosure having an opening formed on a surface thereof; and
a cover which seals the opening, wherein the cover is adapted to move in response to movement of a gas within the enclosure.

2. The speaker device as claimed in claim 1, wherein the cover comprises a material which is not permeable to air.

3. The speaker device as claimed in claim 2, wherein the material which is not permeable to air comprises at least one of resin, textile, vinyl and paper.

4. The speaker device as claimed in claim 1, wherein the cover comprises a foam rubber of an elastomeric system.

5. The speaker device as claimed in claim 4, wherein the cover is attached to the enclosure by a double side tape.

6. The speaker device as claimed in claim 4, wherein the cover comprises a thickness of 13 mm.

7. The speaker device as claimed in claim 1, wherein the opening is formed on a bottom surface of the enclosure.

8. A speaker device for a video display apparatus, comprising:
an enclosure which encloses a speaker unit to form a resonant space; and
a cover which seals an opening formed on a surface of the enclosure,
wherein the cover is formed of a material which is not permeable to air and is adapted to move in response to movement of a gas within the resonant space.

9. The speaker device as claimed in claim 8, wherein the material for the cover comprises a foam rubber of an elastomeric system.

10. The speaker device as claimed in claim 1, wherein the gas is air.

11. The speaker device as claimed in claim 1, further comprising the speaker.

12. The speaker device as claimed in claim 8, wherein the gas is air.

13. The speaker device as claimed in claim 8, further comprising the speaker.

14. A display apparatus which has a speaker device, which is described in claim 1, wherein the speaker device is located right and left of a display unit.

15. A display apparatus which has a speaker device, which is described in claim 8, wherein the speaker device is located right and left of a display unit.

16. The display apparatus as claimed in claim 14, wherein the speaker device is embedded in a lower portion of the display unit in a symmetrical pattern relative to a centerline of the display unit.

17. The display apparatus as claimed in claim 16, wherein the speaker device has a speaker unit which faces downward.

18. The display apparatus as claimed in claim 15, wherein the speaker device is embedded in a lower portion of the display unit in a symmetrical pattern relative to a centerline of the display unit.

19. The display apparatus as claimed in claim 18, wherein the speaker device has a speaker unit which faces downward.
